(19) United States
(12) Patent Application Publication
(10) Pub. No.: US 2016/0312364 A1
(43) Pub. Date: Oct. 27, 2016

(54) ANTI-CORROSION TREATMENT OF A METAL SUBSTRATE AND RESULTING SUBSTRATE

(71) Applicant: ELECTRICITE DE FRANCE, Paris (FR)

(72) Inventors: Xavier Crozes, Le Plessis Robinson (FR); Didier Noel, Avon (FR); Julie Monget, Paris (FR); Abdelhafed Taleb, Ivry sur Seine (FR); Michel Cassir, Paris (FR)

(73) Assignee: ELECTRICITE DE FRANCE, Paris (FR)

(21) Appl. No.: 15/103,549

(22) PCT Filed: Dec. 11, 2014
(86) PCT No.: PCT/FR2014/053295

§ 371 Date: Jun. 10, 2016

(30) Foreign Application Priority Data
Dec. 12, 2013 (FR) 13 62541

(51) Int. Cl. C23C 18/12; C23C 16/455

(52) U.S. Cl. CPC C23C 18/1216; C23C 16/45544; C23C 18/1241; C23C 18/127; C23C 18/1254

(57) ABSTRACT

A method of treating a metal substrate with an anti-corrosion coating comprising at least the following steps: preparing a solution comprising particles of a precursor of the oxide, dipping at least one surface of the metal substrate into the prepared solution and then removing it from the solution, heat treating the surface of the metal substrate in order to generate oxide nanocrystals from the particles of the precursor and form the anti-corrosion coating, and forming a natural oxide layer between the metal substrate and the anti-corrosion coating, the natural oxide layer being enriched with elements from the oxide nanocrystals of the anti-corrosion coating.

The invention relates to a treatment of a metal substrate with an anti-corrosion coating, and to a metal substrate so treated.

It relates in particular to techniques which protect by extrinsic coating of materials exposed to corrosive environments, for example in a primary or secondary fluid circuit of a power station such as a nuclear power plant.

The invention may also apply to shoreline installations, for the protection of marine turbines or wind turbines, or to the field of aeronautics.

More broadly, the invention relates to any field requiring the protection of metals or metal alloys from general corrosion, pitting corrosion, or stress corrosion cracking.

Many methods for obtaining a coating on a metal surface are known in the prior art, in particular a coating formed of oxide nanocrystals.

For example, we can cite various methods for obtaining such a coating: low-pressure spray, a method of atomic layer deposition (ALD), hydrothermal deposition, electrochemical deposition, or dip-withdraw.

The dip-withdraw method is used in particular, which consists in dipping the part to be coated in a solution of the coating and withdrawing it under specified conditions, because it allows formation of the coating at room temperature.

The document “Corrosion protection of 316L stainless steel by a TiO2 nanoparticle coating prepared by a sol-gel method”, 489 (2005) 130-136, (Shen et al.) discloses a method for dip-withdraw a metal substrate with a nanoparticle TiO2 film.

The disadvantage of such a method, however, lies in the fact that it requires a large number of steps and the successive deposition of many layers in order for the coating to be effective against corrosion.

The present invention is intended to overcome such a disadvantage.

To remedy the above problem, the invention provides a method for treating a metal substrate with an anti-corrosion coating composed of a single layer of oxide nanocrystals deposited on the metal substrate, the method comprising at least the following steps:
preparing a solution comprising particles of an oxide precursor;
dipping at least one surface of the metal substrate into the prepared solution and then withdrawing it from the solution in order to cover said surface of the metal substrate at least partially with precursor particles;
heat treating the surface of the metal substrate in order to generate oxide nanocrystals from the precursor particles and form the anti-corrosion coating; and
forming, after corrosion under hydrothermal conditions, a natural oxide layer between the metal substrate and the anti-corrosion coating, the natural oxide layer being enriched with elements from the oxide nanocrystals of the anti-corrosion coating.

The method according to the invention thus requires only one layer of oxide nanocrystals, not a plurality of layers, to form the coating on the metal substrate, and is able to do so in a single dip. The method requires a reduced number of steps, and thus can be applied to bulky and/or large parts at a reduced cost of implementation. In addition, the method can be used to treat a wide variety of metal substrates.

According to one particular embodiment of the invention, the particles of the oxide precursor are obtained after curing the precursor.

According to another particular embodiment, the oxide is a metal oxide. The use of a metal oxide yields a coating that is particularly resistant to corrosion, wear, and erosion in corrosive environments. In addition, a coating composed of metal oxides allows eliminating the use of other compounds, especially organic compounds, which when released can disrupt the chemistry of the environment and which during degradation can result in corrosive species that could damage the pipes in the cooling circuits of a nuclear power plant. It also avoids the release of potentially harmful organic compounds into the environment.

In one particular embodiment, the oxide is selected from the group consisting of TiO₂, ZrO₂ or Cr₂O₃, SiO₂, Al₂O₃, and CeO₂. The oxides of this group are particularly stable chemically, which allows obtaining a particularly resistant coating. In addition, TiO₂ and ZrO₂ have the advantage of being compatible with the environment of a nuclear power plant, particularly a plant comprising a pressurized water reactor.

In one particular embodiment, the anti-corrosion coating has a thickness of less than 300 nm. The reduced thickness of the coating allows using a reduced amount of raw material while coating a large surface area of the metal substrate. In addition, a thin coating reduces the mechanical stresses within the layer of nanocrystals; these stresses can generate cracks and reduce the quality of the anti-corrosion protection.

In one particular embodiment, the oxide precursor solution is obtained by stirring for longer than 10 hours. The duration of the solution preparation step determines the final size of the oxide nanocrystals in the coating. It thus allows obtaining an adherent and continuous coating that conforms to the roughness of the substrate.

In one particular embodiment, the step of dipping the metal substrate surface into the prepared solution and then withdrawing it is conducted at a temperature below 80° C., in particular at a temperature between room temperature and 60° C. The fact that this step is performed at room temperature makes it possible to implement the method as part of the conventional industrial processing, with no need for special heating means that are complex to implement.

In one particular embodiment, the metal substrate surface is withdrawn from the prepared solution at a constant speed of less than 10 millimeters per second. Controlling the speed at which the substrate is withdrawn from the prepared solution allows determining the final thickness of the coating and obtaining a homogeneous and regular coating.

In one particular embodiment, the heat treatment is carried out for at least 30 minutes at a temperature between 300 and 450° C.

In one particular embodiment, the elements of the oxide nanocrystals enriching the natural oxide layer are selected from the group consisting of TiO₂, ZrO₂, Cr₂O₃, SiO₂, Al₂O₃, and CeO₂.

The invention also relates to a metal substrate comprising an anti-corrosion coating obtained by implementing the method.

In one embodiment, the corrosion current of the metal substrate which has the anti-corrosion coating is less than, by at least a factor of 10, the corrosion current of the substrate which does not have the coating.

In a particularly advantageous embodiment, the metal substrate is resistant to general corrosion, pitting corrosion, or stress corrosion cracking, and is suitable for application in a fluid circuit of a nuclear power plant, in particular a primary circuit.

In another and particularly advantageous embodiment, the metal substrate is resistant to corrosion under hydrothermal conditions.

Other features and advantages of the invention will be apparent from the following detailed description, referring to the accompanying drawings in which:

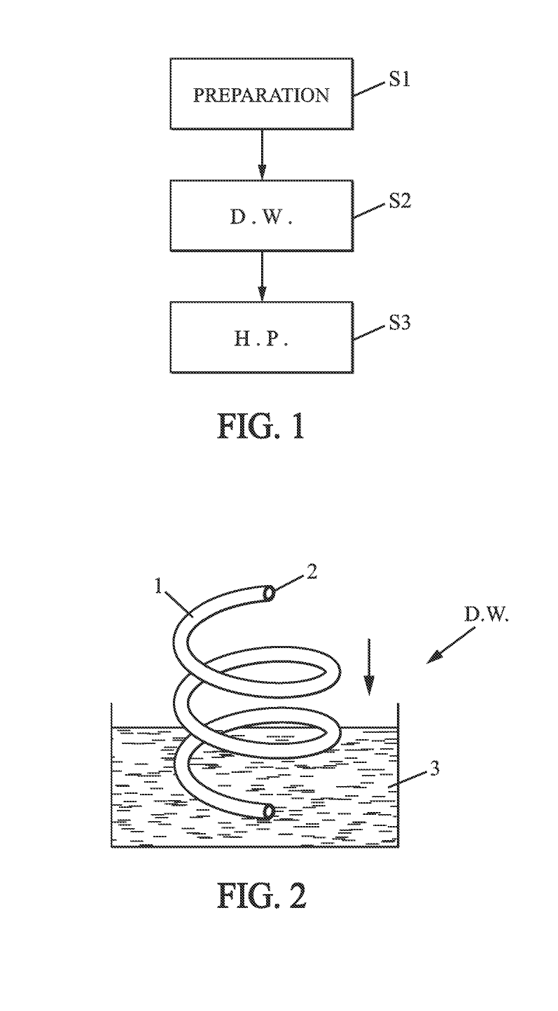

FIG. 1 is a diagram according to an embodiment of the invention;

FIG. 2 is a schematic view of the dip-withdraw step of the method;

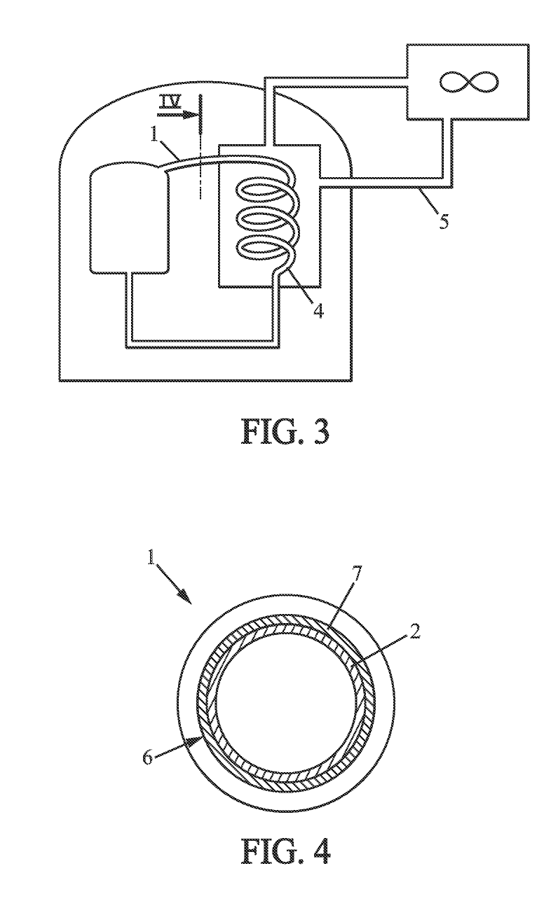

FIG. 3 is a schematic view of the primary and secondary circuits of a nuclear power plant; and

FIG. 4 is a sectional view of a pipe element of the primary circuit of FIG. 3, after treatment by the method according to the invention.

FIG. 1 is a diagram according to an embodiment of the invention, comprising at least three steps S1, S2, and S3 carried out in succession.

In a first step S1 of the invention, a solution 3 is prepared by the hydrolysis-condensation reaction of a precursor of the oxide via the sol-gel route.

The oxide may be a metal oxide. For example, the oxide may be TiO₂ and the oxide precursor may be titanium(IV) butoxide. It is also possible for the oxide to be selected from the group composed of ZrO₂, Cr₂O₃, SiO₂, Al₂O₃, and CeO₂.

For example, the solution 3 prepared according to the first step S1 may be a mixture comprising 20 equivalent volumes (EqV) of ethanol mixed with 1 EqV of ethyl acetoacetate, to which are added 4 EqV of oxide precursor. The mixture is then preferably stirred for at least one hour. Next, 0.2 EqV of water are added to the previously created solution 3 at a controlled rate of addition, preferably 0.005 EqV per minute. The added water hydrolyzes the precursor to form particles of the oxide precursor.

After the water has been added, the solution 3 is stirred for at least 10 hours, possibly even at least 40 hours. The stirring time allows the oxide precursor to cure and determines the final size of the constituent oxide nanocrystals of the anti-corrosion coating (2). Thus, an increase in curing time leads to the formation of larger oxide precursor particles, which, after treatment by the method, leads to larger nanocrystals.

FIG. 2 is a schematic view of the second step S2 of the invention, in which at least one surface 6 of a metal substrate 1 is dipped into the previously prepared solution 3 and is then withdrawn.

This second step S2, the dip-withdraw step (denoted D.W. for “dip/withdraw”), which is preferably carried out at a temperature below 80° C. and more preferably at a temperature between room temperature and 60° C., allows covering all or part (depending on the intended purpose) of the surface 6 of the metal substrate 1 with oxide precursor solution.

The dip-withdraw step (D.W.) can be performed for various types of metal substrate 1, especially for parts having complex geometries. In particular, in the case where the surface 6 consists of the inner surface of a tube as shown in FIG. 2, the dip-withdraw step (D.W.) can be carried out by moving the solution 3 within the tube, in particular by a pumping system or by spray deposition.

The dip-withdraw step (D.W.) can be performed for a wide variety of metal substrates 1, such as carbon steel, stainless steel, or stainless alloys based on nickel, or other alloys or metals used in a nuclear power plant for example.

When withdrawing the metal substrate 1 from the solution 3, the speed is controlled in order to determine the thickness of the nanocrystal layer of the anti-corrosion coating 2. Withdrawal of the metal substrate 1 preferably occurs immediately after dipping the surface 6, for example at a constant speed of less than 10 millimeters per second. In an exemplary embodiment, the withdrawal speed may be about 0.75 millimeters per second.

The dip-withdraw step (D.W.) may further comprise an additional step in which the surface 6 is dried in ambient air after withdrawal from the solution 3.

In a third step S3 according to the invention, the surface 6 of the metal substrate 1 is heat treated (denoted H.P. for “heat processing”) to generate oxide nanocrystals from the precursor particles and to form the anti-corrosion coating 2.

During this step S3, the surface 6 is calcined, preferably between 300 and 450 degrees, for at least 30 minutes. In particular, the calcination atmosphere is controlled to prevent oxidation of the surface 6, which could interfere with formation of the layer of oxide nanocrystals. During this heat treatment step S3, the oxide precursor particles are oxidized to form the oxide nanocrystals.

Prior to calcination of the substrate 1, the method may also comprise an additional step at an intermediate temperature between 100 and 200° C. for a period of between one minute and 10 hours, to polymerize the inorganic portion of the coating and partially eliminate the organic compounds present on the metal substrate 1.

Before performing the D.W. step, the method of the invention may also comprise a step of polishing the treated surface to improve the final corrosion protection, in particular by mechanical, chemical, or electrochemical polishing.

FIG. 4 illustrates a metal substrate 1 having an anti-corrosion coating 2 obtained by implementing the method as described above.

Control of the various steps of the method ensures the proper structure of the layer of oxide nanocrystals and the effectiveness of the anti-corrosion coating 2. In particular, control of the stoichiometry or of the curing duration during the preparation step and/or of the composition of the atmosphere during heat treatment (H.P.) of the surface 6 makes it possible to adapt the method to a wide variety of metal substrates 1 with variable surface states.

It is thus possible to obtain a single homogeneous layer of nanocrystals that is stable, continuous, and of low thickness, preferably less than 300 nanometers, for example 100 nanometers.

When the substrate 1 has an initially high roughness, it is possible to control the curing duration of the solution 3 during the preparation step S1 in order to obtain crystals that are smaller in size than the roughness of the surface 6 of the metal substrate 1, providing satisfactory protection against corrosion.

The anti-corrosion coating 2 thus obtained protects the surface 6 it covers against general corrosion, pitting corrosion, or stress corrosion cracking. It is particularly suitable for application in a fluid circuit of a thermal power station, such as a fossil-fuel power plant or a nuclear power plant, particularly for the primary 4 and secondary 5 circuits as represented in FIG. 3.

Protecting the components of the primary circuit 4, for example tubes of metal alloys or steam generators, reduces the release of metals, particularly nickel, susceptible to neutron activation which can result in exposing workers to radiation. It also prevents stress corrosion cracking of pipes and partition plates of steam generators, when they are of alloy 600 for example.

In addition, an anti-corrosion coating 2 protecting the inner surface of pipes, particularly pipes of carbon steel, that are part of a secondary circuit 5 of a nuclear power plant, helps decrease general corrosion while reducing the fouling and clogging of steam generators.

Similarly, an anti-corrosion coating 2 protecting the brass condensers present in nuclear power plants in the tertiary circuit decreases the release of copper into the environment and reduces the production of pathogenic microorganisms.

These applications specific to nuclear power plants with pressurized water reactors can be extended to other fields, such as wind turbines, marine turbines, applications in the steel and alloy industry which are subject to corrosion, and aeronautics.

The efficacy of the anti-corrosion coating 2 can, for example, be measured using the corrosion current of the metal substrate 1 thus treated when subjected to various corrosive environments. The corrosive environments may, for example, be acidic environments containing H₂SO₄ or H₃BO₃ or a neutral environment containing chloride ions that can degrade the passivity of the metal substrate 1.

In such environments, the corrosion current of the metal substrate 1 which has the anti-corrosion coating 2 is less than, by a factor of 10, the corrosion current of the substrate 1 which does not have the coating 2, or even by a factor of 100.

The anti-corrosion coating 2 also protects against corrosion under hydrothermal conditions. “Hydrothermal conditions” is understood to mean that the metal substrate 1 is located in a medium, particularly an aqueous medium, loaded with dissolved minerals, this medium being under defined temperature and pressure conditions, and in particular at a temperature between room temperature and 360° C. and at a pressure between 1 bar and 155 bar.

Furthermore, as can be seen in FIG. 4, a natural oxide layer 7 is formed on the metal substrate 1. In particular, in the case where the metal substrate 1 has previously been covered by the anti-corrosion coating 2 of the invention, this natural oxide layer 7 is formed between the metal substrate 1 and the anti-corrosion coating 2. The formation of this natural oxide layer 7 is due to natural oxidation of the metal substrate 1. The natural oxide layer 7 can in particular be formed when the metal substrate 1, in particular having the anti-corrosion coating 2, is under hydrothermal conditions.

The thickness of the natural oxide layer 7 so formed depends on the presence and on the properties of the anti-corrosion coating 2. In particular, the thickness of this natural oxide layer 7 is greater if the metal substrate 1 has not been previously coated with anti-corrosion coating 2. The thickness of this natural oxide layer 7 is lower when the metal substrate 1 has been previously coated with anti-corrosion coating 2. The presence of the anti-corrosion coating 2 thus acts on the formation kinetics of the natural oxide layer 7. In particular, the natural oxide layer 7 is formed more slowly when the metal substrate 1 has previously been coated with anti-corrosion coating 2.

In addition, when the metal substrate 1 has previously been coated with anti-corrosion coating 2, the natural oxide layer 7 is, after corrosion under hydrothermal conditions, enriched with elements provided by the oxide nanocrystals constituting the anti-corrosion coating 2. These elements may be the constituent elements of the oxide nanocrystals of the anti-corrosion coating 2. These constituent elements are selected from the group consisting of TiO₂, ZrO₂, Cr₂O₃, SiO₂, Al₂O₃, and CeO₂. The oxide nanocrystals then contribute to doping the natural oxide layer 7, which changes its protective properties. The anti-corrosion coating 2 thus acts by improving the inherent chemical properties of the natural oxide layer 7 and helps to increase the protective nature of the substrate 1 independently of the protective effect of the anti-corrosion coating 2.

The embodiments described above are illustrative of the invention. Various modifications may be made without departing from the scope of the invention as apparent from the appended claims.

1. A method for treating a metal substrate with an anti-corrosion coating composed of a single layer of oxide nanocrystals deposited on the metal substrate, the method comprising at least:
preparing a solution comprising particles of an oxide precursor;
dipping at least one surface of the metal substrate into the prepared solution and then withdrawing it from the prepared solution in order to cover said at least one surface of the metal substrate at least partially with particles of the oxide precursor;
heat treating the at least one surface of the metal substrate in order to generate oxide nanocrystals from the particles of the oxide precursor and form the anti-corrosion coating; and
forming a natural oxide layer between the metal substrate and the anti-corrosion coating, the natural oxide layer being enriched with elements from the oxide nanocrystals of the anti-corrosion coating.

2. The method of claim 1, wherein the particles of the oxide precursor are obtained after curing the oxide precursor.

3. The method of claim 1, wherein the oxide precursor is a metal oxide.

4. The method of claim 1, wherein the oxide precursor is selected from the group consisting of TiO₂, ZrO₂, Cr₂O₃, SiO₂, Al₂O₃, and CeO₂.

5. The method of claim 1, wherein the anti-corrosion coating has a thickness of less than 300 nm.

6. The method of claim 1, further comprising:
stirring the solution for at least 10 hours while preparing the solution.

7. The method of claim 1, further comprising:
conducting the dipping of the surface of the metal substrate into the prepared solution and withdrawing it at a temperature below 80° C., and preferably between room temperature and 60° C.

8. The method of claim 1, further comprising:
withdrawing the surface of the metal substrate from the prepared solution at a constant speed of less than 10 mm/s.

9. The method of claim 1, further comprising:
carrying out the heat treatment of the at least one surface of the metal substrate for at least 30 minutes at a temperature between 300° C. and 450° C.

10. The method of claim 1, wherein the elements of the oxide nanocrystals enriching the natural oxide layer are selected from the group consisting of TiO₂, ZrO₂, Cr₂O₃, SiO₂, Al₂O₃, and CeO₂.

11. A metal substrate, comprising an anti-corrosion coating obtained by implementing a method for treating the metal substrate with an anti-corrosion coating composed of a single layer of oxide nanocrystals deposited on the metal substrate, the method comprising at least:
preparing a solution comprising particles of an oxide precursor;
dipping at least one surface of the metal substrate into the prepared solution and then withdrawing it from the prepared solution in order to cover said at least one surface of the metal substrate at least partially with particles of the oxide precursor;
heat treating the at least one surface of the metal substrate in order to generate oxide nanocrystals from the particles of the oxide precursor and form the anti-corrosion coating; and
forming a natural oxide layer between the metal substrate and the anti-corrosion coating, the natural oxide layer being enriched with elements from the oxide nanocrystals of the anti-corrosion coating.

12. The metal substrate according to claim 11, wherein a corrosion current of the metal substrate which has the anti-corrosion coating is less than, by at least a factor of 10, a corrosion current of the metal substrate which does not have the anti-corrosion coating.

13. The metal substrate according to claim 11, wherein the metal substrate is resistant to general corrosion, pitting corrosion, or stress corrosion cracking, and is suitable for application in a fluid circuit of a nuclear power plant, in particular a primary circuit.

14. The metal substrate according to claim 11, wherein the metal substrate is resistant to corrosion under hydrothermal conditions.
